(19) United States
(12) Patent Application Publication
(10) Pub. No.: US 2014/0124255 A1
(43) Pub. Date: May 8, 2014

(54) METHOD FOR MANUFACTURING ELECTRONIC COMPONENT-EMBEDDED SUBSTRATE AND ELECTRONIC COMPONENT-EMBEDDED SUBSTRATE

(71) Applicant: SAMSUNG ELECTRO-MECHANICS CO., LTD., Suwon (KR)

(72) Inventor: Bong Soo KIM, Yeongi-gun (KR)

(73) Assignee: SAMSUNG ELECTRO-MECHANICS CO., LTD., Suwon (KR)

(21) Appl. No.: 14/070,006

(22) Filed: Nov. 1, 2013

(30) Foreign Application Priority Data
Nov. 2, 2012 (KR) 10-2012-0123491

(51) Int. Cl. H05K 3/42; H05K 1/18

(52) U.S. Cl. CPC H05K 3/429; H05K 1/184
USPC 174/260; 29/837

(57) ABSTRACT

Disclosed herein are a method for manufacturing an electronic component-embedded substrate and an electronic component-embedded substrate. The method includes: inserting an electronic component having an external electrode into a cavity penetrating through a core substrate; forming a multilayer body in which the electronic component is embedded by stacking an insulating layer on upper and lower portions of the core substrate; forming a through-hole exposing the external electrode of the electronic component and penetrating through the multilayer body; and filling the through-hole with a conductive material.

### CROSS REFERENCE(S) TO RELATED APPLICATIONS

This application claims the benefit under 35 U.S.C. Section 119 of Korean Patent Application Serial No. 10-2012-0123491, entitled “Method for Manufacturing Electronic Component-Embedded Substrate and Electronic Component-Embedded Substrate” filed on Nov. 2, 2012, which is hereby incorporated by reference in its entirety into this application.

### BACKGROUND OF THE INVENTION

1. Technical Field

The present invention relates to a method for manufacturing an electronic component-embedded substrate and an electronic component-embedded substrate. Specifically, the present invention relates to a method for manufacturing an electronic component-embedded substrate of forming the electronic component-embedded substrate by allowing a part of an external electrode of the embedded electronic component to be exposed to an inner portion of a through-hole and filling a conductive material to the through-hole and an electronic component-embedded substrate.

2. Description of the Related Art

In accordance with miniaturization, densification, and thinning of an electronic component, research into the thinning and multi-functioning of a semiconductor package substrate has also been actively conducted. As an electronic product is miniaturized and performance thereof is improved, use of an embedded substrate in which a miniaturized electronic component is embedded has increased.

For example, a small multilayer ceramic capacitor (MLCC) is recently embedded in the substrate used in a mobile terminal and in accordance with the future trend toward miniaturization thereof, small components having a smaller size need to be embedded in a smaller cavity.

In general, in the embedded substrate in which the electronic component is embedded, a via hole connecting an external electrode of an embedded-component to a circuit pattern on the substrate has been manufactured so as to be seated on the external electrode. However, as the electronic product is miniaturized and performance thereof is improved, accuracy of an alignment has become important in order to mount the electronic component having a smaller size in a small cavity space and accurately seat the via hole on the external electrode in connecting the external electrode of the electronic component to the circuit pattern of the substrate.

Particularly, in the case in which a micro-size electronic component is embedded, for example, in the case in which the MLCC having the small size is embedded, a registration of the via hole connecting an external electrode pad of the MLCC to the circuit of an upper layer has gradually become difficult, such that it is difficult to align the via hole without eccentricity.

### RELATED ART DOCUMENT

### Patent Document

(Patent Document 1) Korean Patent Laid-Open Publication No. 10-2006-0005840 (laid-open published on Jan. 18, 2006)

### SUMMARY OF THE INVENTION

An object of the present invention is to provide a technology capable of easily connecting an external electrode to a circuit pattern of an embedded substrate by forming a through-hole so as to expose the external electrode without seating the via hole on the external electrode pad in order to connect the external electrode of the embedded electronic component to the circuit pattern of the embedded substrate.

According to an exemplary embodiment of the present invention, there is provided a method for manufacturing an electronic component-embedded substrate, the method including: inserting an electronic component having an external electrode into a cavity penetrating through a core substrate; forming a multilayer body in which the electronic component is embedded by stacking an insulating layer on upper and lower portions of the core substrate; forming a through-hole exposing the external electrode of the electronic component and penetrating through the multilayer body; and filling the through-hole with a conductive material.

In the forming of the through-hole, the external electrode may be exposed to an inner portion of the through-hole through a CO₂ laser processing.

In the filling of the conductive material, the electronic component-embedded substrate may be formed by filling the through-hole with a conductive paste.

In the filling of the through-hole with the conductive material, the through-hole may be filled with the conductive material through a plating process.

The method may further include forming a stack via structure by stacking an additional insulating layer on the multilayer body in which the through-hole is filled and forming a via hole penetrating through the additional insulating layer over the through-hole.

The forming of the multilayer body may include forming a conductive layer on the insulating layer after stacking the insulating layer on the upper and lower portions of the core substrate.

The electronic component may be a multilayer capacitor having the external electrode formed on both sides thereof, and in the forming of the through-hole, a part of each of both sides of the external electrode may be exposed.

According to another exemplary embodiment of the present invention, there is provided an electronic component-embedded substrate, including: a core substrate having a cavity formed therein; an electronic component embedded in the cavity and having an external electrode; an insulating layer stacked on upper and lower portions of the core substrate; and a conductive through-hole formed by filling a through-hole exposing the external electrode of the electronic component and penetrating through an upper and lower portions of the insulating layer with a conductive material.

The conductive through-hole may have a width which becomes narrower from the upper and lower portions of the insulating layer toward an inner portion thereof.

The electronic component-embedded substrate may further include: an additional insulating layer additionally stacked on the insulating layer in which the conductive through-hole is formed; and a stack via hole penetrating through the additional insulating layer and seating on the conductive through-hole to form a stack via structure.

The electronic component may be a multilayer capacitor having the external electrode formed on both sides thereof and a part of each of both sides of the external electrode may be exposed to an inner portion of the conductive through-hole.

### BRIEF DESCRIPTION OF THE DRAWINGS

FIGS. 1A to 1G are views schematically showing each of steps of a method for an electronic component-embedded substrate according to an exemplary embodiment of the present invention; and

FIG. 2 is a view schematically showing an electronic component-embedded substrate according to an exemplary embodiment of the present invention.

### DESCRIPTION OF THE PREFERRED EMBODIMENTS

Exemplary embodiments of the present invention for accomplishing the above-mentioned objects will be described with reference to the accompanying drawings. In the present specification, the same reference numerals will be used to describe the same components, and a detailed description thereof will be omitted in order to allow those skilled in the art to easily understand the present invention.

In the specification, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

Although a singular form is used in the present description, it may include a plural form as long as it is opposite to the concept of the present invention and is not contradictory in view of interpretation or is used as a clearly different meaning. It should be understood that “include”, “have”, “comprise”, “be configured to include”, and the like, used in the present description do not exclude presence or addition of one or more other characteristic, component, or a combination thereof.

The accompanying drawings referred in the present description may be ideal or abstract examples for describing exemplary embodiments of the present invention. In the accompanying drawings, a shape, a size, a thickness, and the like, may be exaggerated in order to effectively describe technical characteristics.

First, a method for manufacturing an electronic component-embedded substrate according to a first embodiment of the present invention will be specifically described with reference to drawings. Here, reference numerals which are not described in the referred drawings may be reference numerals showing the same configuration in other drawings.

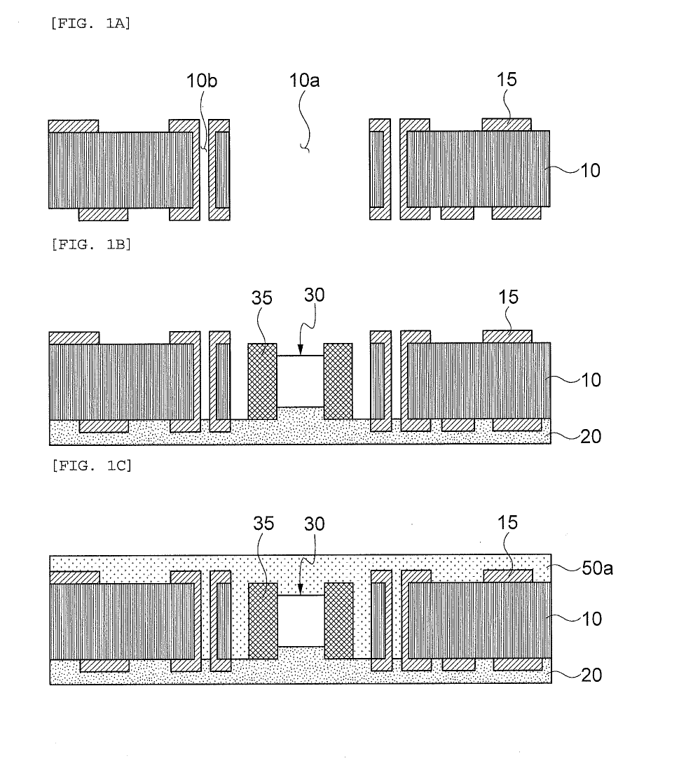

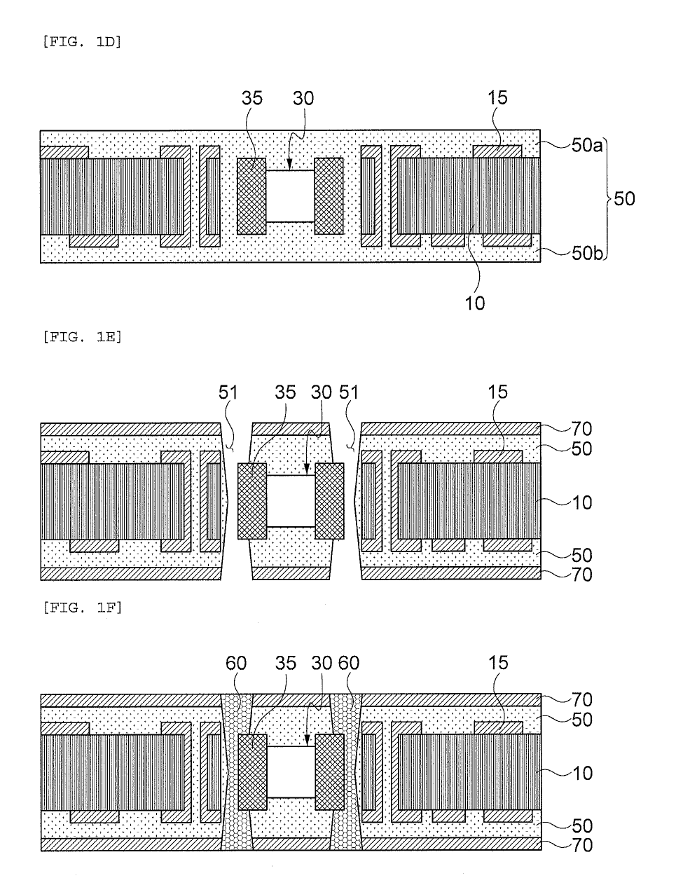

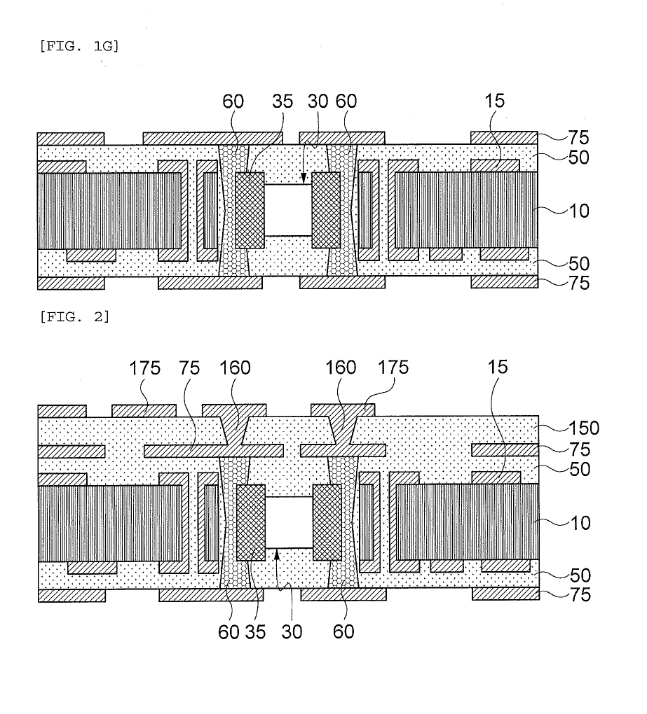

FIGS. 1A to 1G are views schematically showing each of steps of a method for an electronic component-embedded substrate according to an exemplary embodiment of the present invention; and FIG. 2 is a view schematically showing an electronic component-embedded substrate according to an exemplary embodiment of the present invention.

Referring to FIGS. 1A to 1G, the method for manufacturing the electronic component-embedded substrate according to one example may include inserting an electronic component (see FIGS. 1A and 1B), forming a multilayer body (see FIGS. 1C and 1D), forming a through-hole (see FIG. 1E), and filling the through-hole (FIGS. 1F and 1G). In addition, referring to one example with reference to FIG. 2, the method for manufacturing the electronic component-embedded substrate may further include forming a stack via structure (see FIG. 2). A detailed description thereof will be provided below.

First, referring to FIGS. 1A and 1B, in the inserting of the electronic component, the electronic component 30 having an external electrode 35 is inserted into a cavity 10a penetrating through a core substrate 10. Here, the electronic component 30 may be a passive element or an active element, for example, a multilayer capacitor having the external electrode 35 formed on both sides thereof.

Referring to FIGS. 1A and 1B, a description thereof will be provided in detail. In one example, the inserting of the electronic component may include preparing the core substrate (see FIG. 1A) and inserting the electronic component (see FIG. 1B). Here, referring to FIG. 1A, in the preparing of the core substrate, the core substrate 10 having the cavity 10a formed therein is prepared. The cavity 10a may be formed using a CNC, a laser, or the like. In addition, for example, as shown in FIG. 1A, the core substrate 10 may have the through-hole 10b formed therein in addition to the cavity 10a and may have the circuit pattern 15 formed on surfaces of an upper and lower portions thereof. Next, referring to FIG. 1B, in the inserting of the electronic component, the electronic component 30 having an external electrode 35 is inserted into the cavity 10a of the core substrate 10. For example, after the lower portion of the core substrate 10 having the cavity 10a formed therein is closed using an adhesive film 20, the electronic component 30 is attached onto the adhesive film 20 in the cavity 10a, thereby fixing the electronic component 30 thereto.

Next, referring to FIGS. 1C and 1D, in the forming of the multilayer body, an insulating layer 50 is stacked on the upper and lower portions of the core substrate 10, thereby forming the multilayer body having the electronic component 30 embedded therein. Here, referring to FIGS. 1C and 1D, in the forming of the multilayer body, for example, stacking of the insulating layer, the insulating layer 50 is stacked on the upper and lower portions of the core substrate 10 into which the electronic component 30 is inserted. Here, the multilayer body may be formed by compressing the insulating layer using a press. Referring to FIG. 1C, an upper insulating layer 50a may be formed so as to allowing an insulating material to be introduced into a space between an inner wall of the cavity 10a and the external electrode 35 by stacking and compressing the insulating layer 50a on the core substrate 10 into which the electronic component 30 is inserted. Next, as shown in FIG. 1D, the multilayer body may be formed by removing the adhesive film 20 attached to the lower portion of the core substrate, for example and stacking and compressing an insulating layer 50b on the lower portion. In this case, the lower insulating layer 50b and the upper insulating layer 50a may be made of the same material.

In addition, referring to FIG. 1E, in one example, the forming of the multilayer body may further include forming a conductive layer 70 on the insulating layer 50 after stacking the insulating layer 50 on the upper and lower portions of the core substrate 10. That is, in FIGS. 1C and 1D, after the multilayer body is formed by stacking and compressing the insulating layer 50 on the upper and lower portions of the core substrate 10 into which the electronic component 30 is inserted, the conductive layer 70 may be formed by forming a copper foil layer on the surfaces of the upper and lower portions of the insulating layer 50.

Next, referring to FIG. 1E, in the forming of the through-hole, the through-hole 51 penetrating through the multilayer body is formed while the external electrode 35 of the embedded electronic component 30 is exposed. According to the related art, in the case of the electronic component-embedded substrate, the via hole (not shown) connected to the external electrode is seated on the external electrode. However, in accordance with the miniaturization of the electronic component, for example, the multilayer capacitor which is the passive element, it is difficult to accurately seat the via hole for connecting an external circuit pattern to the external electrode on the external electrode. However, according to the exemplary embodiment of the present invention, it is possible to easily solve the problem of the alignment accuracy by forming the through-hole 51 penetrating through the space between the external electrode 35 and the inner wall of the cavity 10a so as to expose the part of the external electrode 35 of the electronic component 30, without connecting the external circuit pattern to the external electrode of the embedded electronic component through the via hole (not shown) as in the case according to the related art.

For example, in the case of the multilayer capacitor in which the electronic component 30 has the external electrodes 35 formed at both sides thereof, in the forming of the through-hole, the part of each of both sides of the external electrode 35 may be exposed to an inner portion of the through-hole 51.

In addition, according to one example, in the forming of the through-hole, the through-hole 51 may be formed by exposing the external electrode 35 of the electronic component 30 through a CO₂ laser processing. At the time of general CO₂ laser processing, since CO₂ laser does not penetrate through a metal electrode, for example, a copper electrode, the through-hole 51 may be processed over the space between the external electrode 35 and the cavity 10a and a part of the external electrode 35 using the CO₂ laser. In this case, since the multilayer body is processed at both sides of the upper and lower portions thereof using the CO₂ laser, the through-hole 51 has a structure in which a width thereof becomes narrower from the surface of the multilayer body toward the inner portion thereof. That is, in accordance with the CO₂ laser processing, it is possible to form the through-hole 51 penetrating through the space between the external electrode 35 and the inner wall of the cavity 10a so that the part of the external electrode 35 of the electronic component 30 is more easily exposed.

Next, referring to FIGS. 1F and 1G, in the filling of the through-hole, the through-hole 51 is filled with a conductive material. The through-hole which is filled with the conductive material becomes a conductive through-hole 60. As the conductive material, for example, copper is used. However, the conductive material is not limited thereto. The through-hole 51 is filled with the conductive material as shown in FIG. 1F and a pattern is then formed in an outside conductive layer 70 of the multilayer body in which the conductive through-hole 60 is formed as shown in FIG. 1G, thereby making it possible to form a circuit pattern 75.

In this case, according to one example, in the filling of the through-hole, the through-hole 51 may be filled with a conductive paste. In the case in which the conductive paste is filled into the through-hole 51, the conductive paste may also be evenly filled into the surface of the multilayer body, such that the problem such as a dimple does not occur.

In addition, in another example, in the filling of the through-hole, the through-hole 51 may be filled with a conductive material through a plating process. Here, an electrolysis plating method or an electroless plating method may be used.

In addition, further referring to FIG. 2, in one example, the method for manufacturing the electronic component-embedded substrate may further include the forming of the stack via structure. As described above, referring to FIGS. 1F and/or 1G, in the filling of the through-hole, the through-hole 51 is filled with the conductive material. In addition, referring to FIG. 2, in the forming of the stack via structure, an additional insulating layer 150 is stacked on the multilayer body in which the through-hole is filled and a stack via hole 160 penetrating through the additional insulating layer 150 over the conductive through-hole 60 is formed. Therefore, the substrate having the stack via structure formed therein may be formed. For example, after through-hole 51 is filled with the conductive paste as the conductive material so as to even the surface thereof, the additional insulating layer 150 may be stacked and the stack via hole 160 may be formed over the through-hole 60 which is filled with the conductive paste.

Next, an electronic component-embedded substrate according to a second embodiment of the present invention will be specifically described with reference to the drawings. Here, the method for manufacturing the electronic component-embedded substrate according to the first embodiment will be referred to and thus, the overlapped descriptions may be omitted.

FIGS. 1F and/or 1G show an electronic component-embedded substrate according to one example of the present invention and FIG. 2 shows an electronic component-embedded substrate according to another example of the present invention.

Referring to FIGS. 1F, 1G and/or 2, the electronic component-embedded substrate according to one example includes the core substrate 10, the electronic component 30, the insulating layer 50, and the conductive through-hole 60.

Here, the core substrate 10 has the cavity 10 formed therein. For example, the core substrate 10 may include the through-hole 10b electrically connecting between the upper and lower portions of the core substrate 10 in addition to the cavity 10a and the circuit pattern 15 may be formed on the upper and lower portions of the core substrate 10.

In addition, the electronic component 30 has the external electrode 35 and is embedded in the cavity 10a. For example, the electronic component 30 may be the passive element or the active element and in one example, may be the multilayer capacitor having the external electrode 35 formed on both sides thereof. For example, in the case in which the electronic component 30 is the multilayer capacitor having the external electrodes 35 formed at both sides thereof, the part of each of both sides of the external electrode 35 may be embedded so as to be exposed to the inner portion of the through-hole 60, thereby making it possible to electrically connect to the conductive through-hole 60.

In addition, the insulating layer 50 is stacked on the upper and lower portions of the core substrate 10. For example, an unprocessed conductive layer 70 or a circuit pattern in which the conductive layer is processed may be formed on the insulating layer 50.

Next, the conductive through-hole 60 exposes the external electrode 35 of the electronic component 30 and is formed by filling the through-hole 51 penetrating through the upper and lower portions of the insulating layer 50 with the conductive material. Therefore, when a small element component such as a small capacitor or the like, for example, 0402 size or the like, is embedded, it is possible to overcome the problem of alignment accuracy for connecting the external electrode 35 to the circuit pattern of the multilayer.

For example, in one example, the conductive through-hole 60 may be formed so as to have the width thereof which becomes narrower from the surfaces of the upper and lower portions of the insulating layer 50 toward the inner portion thereof.

In addition, referring to one example with reference to FIG. 2, the electronic component-embedded substrate may further include the additional insulating layer 150 and the stack via hole 160. Here, the additional insulating layer 150 is additionally stacked on the insulating layer 50 in which the conductive through-hole 60 is formed. In addition, the stack via hole 160 penetrates through the additional insulating layer 150 and seats on the conductive through-hole 60, thereby forming the stack via structure. For example, referring to FIG. 2, the circuit pattern 75 may be formed on the upper and lower portions of the insulating layer 50 having the conductive through-hole 60 formed therein and the circuit pattern 175 may also be formed on the additional insulating layer 150.

According to the exemplary embodiment of the present invention, it is possible to easily connect the external electrode to the circuit pattern of the embedded substrate by forming the through-hole so as to expose the external electrode without seating the via hole on the external electrode pad in order to connect the external electrode of the embedded electronic component to the circuit pattern of the embedded substrate.

That is, it is possible to easily solve the problem of the alignment accuracy by forming the through-hole penetrating through the space between the external electrode and the inner wall of the cavity so as to expose the external electrode of the electronic component, without connecting the external circuit pattern to the external electrode of the electronic component through the via hole as in the case according to the related art.

It is obvious that various effects directly stated according to various'exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains rather than limiting a scope of the present invention. In addition, exemplary embodiments according to a combination of the above-mentioned configurations may be obviously implemented by those skilled in the art. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

1. A method for manufacturing an electronic component-embedded substrate, the method comprising:
inserting an electronic component having an external electrode into a cavity penetrating through a core substrate;
forming a multilayer body in which the electronic component is embedded by stacking an insulating layer on upper and lower portions of the core substrate;
forming a through-hole exposing the external electrode of the electronic component and penetrating through the multilayer body; and
filling the through-hole with a conductive material.

2. The method according to claim 1, wherein in the forming of the through-hole, the external electrode is exposed to an inner portion of the through-hole through a CO₂ laser processing.

3. The method according to claim 1, wherein in the filling of the through-hole with the conductive material, the electronic component-embedded substrate is formed by filling the through-hole with a conductive paste.

4. The method according to claim 1, wherein in the filling of the through-hole with the conductive material, the through-hole is filled with the conductive material through a plating process.

5. The method according to claim 1, further comprising forming a stack via structure by stacking an additional insulating layer on the multilayer body in which the through-hole is filled and forming a via hole penetrating through the additional insulating layer over the through-hole.

6. The method according to claim 1, wherein the forming of the multilayer body includes forming a conductive layer on the insulating layer after stacking the insulating layer on the upper and lower portions of the core substrate.

7. The method according to claim 1, wherein the electronic component is a multilayer capacitor having the external electrode formed on both sides thereof,
in the forming of the through-hole, a part of each of both sides of the external electrode is exposed.

8. An electronic component-embedded substrate, comprising:
a core substrate having a cavity formed therein;
an electronic component embedded in the cavity and having an external electrode;
an insulating layer stacked on upper and lower portions of the core substrate; and
a conductive through-hole formed by filling a through-hole exposing the external electrode of the electronic component and penetrating through an upper and lower portions of the insulating layer with a conductive material.

9. The electronic component-embedded substrate according to claim 8, wherein the conductive through-hole has a width which becomes narrower from the upper and lower portions of the insulating layer toward an inner portion thereof.

10. The electronic component-embedded substrate according to claim 8, further comprising:
an additional insulating layer additionally stacked on the insulating layer in which the conductive through-hole is formed; and
a stack via hole penetrating through the additional insulating layer and seating on the conductive through-hole to form a stack via structure.

11. The electronic component-embedded substrate according to claim 8, wherein the electronic component is a multilayer capacitor having the external electrode formed on both sides thereof,
a part of each of both sides of the external electrode is exposed to an inner portion of the conductive through-hole.

12. The method according to claim 2, wherein the electronic component is a multilayer capacitor having the external electrode formed on both sides thereof,
in the forming of the through-hole, a part of each of both sides of the external electrode is exposed.

13. The method according to claim 3, wherein the electronic component is a multilayer capacitor having the external electrode formed on both sides thereof,
in the forming of the through-hole, a part of each of both sides of the external electrode is exposed.

14. The method according to claim 4, wherein the electronic component is a multilayer capacitor having the external electrode formed on both sides thereof,
in the forming of the through-hole, a part of each of both sides of the external electrode is exposed.

15. The method according to claim 5, wherein the electronic component is a multilayer capacitor having the external electrode formed on both sides thereof,
in the forming of the through-hole, a part of each of both sides of the external electrode is exposed.

16. The method according to claim 6, wherein the electronic component is a multilayer capacitor having the external electrode formed on both sides thereof,
in the forming of the through-hole, a part of each of both sides of the external electrode is exposed.

17. The electronic component-embedded substrate according to claim 9, wherein the electronic component is a multilayer capacitor having the external electrode formed on both sides thereof,
a part of each of both sides of the external electrode is exposed to an inner portion of the conductive through-hole.

18. The electronic component-embedded substrate according to claim 10, wherein the electronic component is a multilayer capacitor having the external electrode formed on both sides thereof,
a part of each of both sides of the external electrode is exposed to an inner portion of the conductive through-hole.
